(19) United States
(12) Patent Application Publication
(10) Pub. No.: US 2014/0076374 A1
(43) Pub. Date: Mar. 20, 2014

(54) CONCATENATION OF INTERCONNECTED POLYMER SOCKETS FOR BACK-CONTACT PHOTOVOLTAIC CELLS

(71) Applicant: PETROS DAFNIOTIS, Geneva (CH)

(72) Inventor: PETROS DAFNIOTIS, Geneva (CH)

(73) Assignee: E I DU PONT DE NEMOURS AND COMPANY, Wilmington, DE (US)

(21) Appl. No.: 14/031,351

(22) Filed: Sep. 19, 2013

Related U.S. Application Data
(60) Provisional application No. 61/703,415, filed on Sep. 20, 2012.

(51) Int. Cl. H01L 31/05

(52) U.S. Cl. CPC H01L 31/0516
USPC 136/244; 438/98

(57) ABSTRACT

A concatenation of interconnected polymer sockets are provide for accepting and electrically connecting a back-contact photovoltaic cells having at least one set of linearly arranged backface emitter contacts and at least one set of linearly arranged backface collector contacts. A process for manufacturing the concatenation of interconnected polymer sockets for accepting and electrically connecting back-contact photovoltaic cells is also provided.

### FIELD OF THE INVENTION

The present invention relates to a concatenation of interconnected polymer sockets for back-contact photovoltaic cells and to a process for the manufacture thereof.

### BACKGROUND OF THE INVENTION

Photovoltaic cells, sometimes called solar cells or photoactive cells, can convert light, such as sunlight, into electrical energy.

In practice, a plurality of photovoltaic cells is electrically connected together in series or in parallel to form an array of photovoltaic cells which can be incorporated into a photovoltaic module.

In order to increase the voltage delivered by individual photoactive cells to a suitable level, the cells are conventionally connected in series.

A serial connection between the cells of a module can be achieved by connecting the emitter contact of one photovoltaic cell to the collector contact of the next (adjacent) cell, usually by soldering an electrical conductor such as wire, tape or ribbon to the contacts of the adjacent cell.

In most of today's photovoltaic modules, the photovoltaic cells that convert light into electrical energy are H-type cells, in which the emitter contacts and collector contacts are located on opposite sides of the cells. The emitter contacts are located on the front surface, i.e. the surface exposed to the sunlight, whereas the collector contacts are on the back side. FIG. 1A shows the frontface of an H-type photovoltaic cell E having two emitter contacts (D1, D2), also known as emitter bus bars. FIG. 1B shows the backface of an H-type photovoltaic cell E having two collector contacts (F1, F1), also known as collector bus bars. A skilled person will recognize that the emitter contacts and the collector contacts are of opposite polarity.

The electrical conductors connecting two cells are soldered such that the front emitter contacts of one photovoltaic cell are connected with one or more back collector contacts of the adjacent photovoltaic cell. On an industrial scale, the electrical conductors are applied to the cell contacts by way of automated soldering equipment (so-called “tabber-stringer”).

However, when soldered to the front emitter contacts, the electrical conductors cover a portion of the available photovoltaic surface of the cell, which in turn reduces the amount of electrical energy that can be produced by the cell.

New cell types have been developed in which the emitter contacts have been moved from the front face to the back face of the photovoltaic cell in order to free up an additional portion of front surface and increase the amount of electrical energy that can be produced by the cell.

Such photovoltaic cells, in which both emitter and collector contacts are located on the back side of the cell, are known under the common designation “back-contact cells”, which designation encompasses metallization wrap-through (MWT) cells, back-junction (BJ) cells, integrated back contact (IBC) cells and emitter wrap-through (EWT) cells.

Moving from traditional H-type cells having front emitter contacts to back-contact cells having back emitter contacts requires drastic changes in the structure of the photovoltaic module itself, such as for example a complete redesign of the electrical connections between the cells. Concurrently, these structural changes in the photovoltaic module also require a redesign of the manufacturing equipment as well as changes in the module manufacturing method.

WO2006/123938 describes a method of contacting MWT cells by tabbing and stringing. However, the proposed method requires the use of extensive amounts of an insulating material, which is economically discouraging. Furthermore, applying significant amounts of insulating material as well as the electrical conductors on the rear side of a cell creates local unevenness that will warp the cell during the lamination step of module production. The warpage induces mechanical strains in the cell, which results in a lessened degree of efficiency, and also results in the formation of cracks.

The above described changes make the purchase of new manufacturing equipment inevitable for a module manufacturer desiring to use back-contact cells, which presents a considerable economic hurdle for the adoption of back-contact cells in photovoltaic modules. It would therefore be desirable to provide for a means that allows the manufacturing of photovoltaic modules incorporating back-contact cells, but without the need of entirely replacing or considerably altering existing manufacturing equipment and thus make the change more economically feasible.

### SUMMARY OF THE INVENTION

The present invention provides for a concatenation of interconnected polymer sockets each for accepting and electrically connecting a back-contact photovoltaic cell having at least one set of linearly arranged backface emitter contacts and at least one set of linearly arranged backface collector contacts, each polymer socket comprising (a) a planar, electrically insulating polymer substrate comprising perforations coinciding with the backface emitter contacts, and (b) at least one electrical conductor being collinear with the perforations of the planar polymer substrate coinciding with the at least one set of linearly arranged backface emitter contacts, the at least one electrical conductor being adhered to the backface of the planar polymer substrate, wherein the at least one electrical conductor of each polymer socket, except the last one in the concatenation, is adhered to the frontface of one adjacent polymer socket so as to be collinear with the at least one set of linearly arranged backface collector contacts of the back-contact photovoltaic cell to be accepted and electrically connected by said adjacent polymer socket, wherein the back-contact photovoltaic cells to be accepted and electrically connected by adjacent polymer sockets are rotated by 180° with respect to each other.

The present invention further provides for a process for manufacturing a concatenation of interconnected polymer sockets each for accepting and electrically connecting a back-contact photovoltaic cell having at least one set of linearly arranged backface emitter contacts and at least one set of linearly arranged backface collector contacts, the process comprising the steps of (a) providing planar, electrically insulating polymer substrates having perforations coinciding with the backface emitter contacts of the back-contact photovoltaic cells to be accepted and electrically connected by the polymer sockets comprising said substrates, and (b) interconnecting said planar, electrically insulating polymer substrates to form the concatenation of interconnected polymer sockets, such that the backface of each polymer substrate, except the last one in said concatenation, is connected to the frontface of one adjacent polymer substrate by at least one electrical conductor, wherein said at least one electrical conductor is collinear with (i) the perforations of the planar, electrically insulating polymer substrate coinciding with the at least one set of linearly arranged backface emitter contacts of the back-contact photovoltaic cells to be accepted and electrically connected by each of the polymer sockets comprising said polymer substrates, and (ii) the at least one set of linearly arranged backface collector contacts of the back-contact photovoltaic cell to be accepted and connected by the one adjacent polymer socket, wherein the back-contact photovoltaic cells to be accepted and electrically connected by adjacent polymer sockets are rotated by 180° with respect to each other.

### BRIEF DESCRIPTION OF THE DRAWINGS

FIG. 1A shows the frontface of an H-type photovoltaic cell.

FIG. 1B shows the backface of an H-type photovoltaic cell.

FIG. 2 shows the frontface of a MWT photovoltaic cell.

FIG. 3 shows the backface of a MWT photovoltaic cell of FIG. 2.

FIG. 4 shows an exploded view of a plurality of MWT cells and a plurality of polymeric sockets electrically interconnected to form a concatenation of interconnected polymer sockets and photovoltaic cells.

FIG. 5A shows the frontface of a planar, electrically insulating polymer substrate of a polymeric socket.

FIG. 5B shows a cross-sectional side view of the electrically insulating polymer substrate of FIG. 5A.

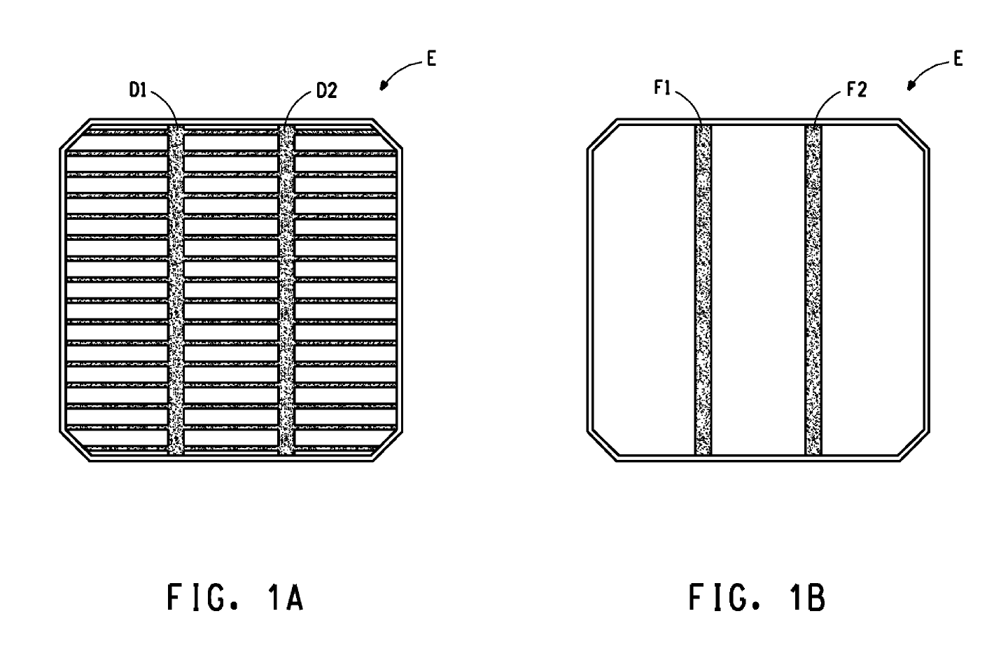

### DETAILED DESCRIPTION

For the purpose of the present disclosure, the term “backface” or “back” denotes the surface of a photovoltaic cell in a photovoltaic module, or of any other planar element in a photovoltaic module, such as in particular the polymer sockets of the concatenation of the present invention, which faces away from incident light, i.e. which faces towards the back sheet of the photovoltaic module.

For the purpose of the present disclosure, the term “frontface” or “front” denotes the surface of a photovoltaic cell in a photovoltaic module, or of any other planar element in a photovoltaic module, such as in particular the polymer sockets of the concatenation of the present invention, which faces towards incident light, i.e. which faces away from the back sheet and towards the front sheet of the photovoltaic module.

For the purpose of the present disclosure, the term “light” means any type of electromagnetic radiation that can be converted into electric energy by a photovoltaic cell.

For the purpose of the present disclosure, the terms “photoactive” and “photovoltaic” may be used interchangeably and refer to the property of converting radiant energy (e.g., light) into electrical energy.

For the purpose of the present disclosure, the terms “photovoltaic cell” or “photoactive cell” means an electronic device that can convert electromagnetic radiation (e.g., light) into an electrical signal. A photovoltaic cell includes a photoactive material layer that may be an organic or inorganic semiconductor material that is capable of absorbing radiation and converting it into electrical energy. The terms “photovoltaic cell” or “photoactive cell” are used herein to include solar cells with any types of photoactive layers including crystalline silicon, amorphous silicon, cadmium telluride, and copper indium gallium selenide (CIGS) photoactive layers.

For the purpose of the present disclosure, the term “photovoltaic module” (also “module” for short) means any electronic device having at least one photovoltaic cell.

For the purpose of the present disclosure, the term “encapsulant layer” refers to a layer of material that is designed to protect the photoactive cells from degradation caused by chemical and/or mechanical stress.

For the purpose of the present disclosure, the term “front encapsulant layer” refers to an encapsulant layer that is located between the frontface of a photoactive cell and the front sheet of the module.

For the purpose of the present disclosure, the term “back encapsulant layer” refers to an encapsulant layer that is located between the backface of a photoactive cell and the back sheet of the module.

For the purpose of the present disclosure, the term “ionomer” means and denotes a thermoplastic resin containing both covalent and ionic bonds derivable from ethylene copolymers. Ionomers may be obtained by partial neutralization of ethylene-methacrylic acid copolymers or ethylene-acrylic acid copolymers with inorganic bases having cations of elements from Groups I, II, or III of the Periodic table, notably, sodium, aluminum, lithium, magnesium, and barium may be used, or transition metals such as zinc. The term “ionomer” and the resins identified thereby are well known in the art, as evidenced by Richard W. Rees, “Ionic Bonding In Thermoplastic Resins”, DuPont Innovation, 1971, 2(2), pp. 1-4, and Richard W. Rees, “Physical Properties And Structural Features Of Surlyn Ionomer Resins”, Polyelectrolytes, 1976, C, 177-197.

For the purpose of the present disclosure, the term “emitter contact” means and denotes an electrical contact connecting the emitter of a photovoltaic cell to an electrical conductor. In the case of a back-contact photovoltaic cell such as MWT cells, the emitter contacts are the so-called “vias”, or “back emitter contacts”, located on the backface of the cell.

For the purpose of the present disclosure, the term “collector contact” means and denotes an electrical contact connecting the collector of a photovoltaic cell to an electrical conductor. In the case of a back-contact photovoltaic cell such as MWT cells, the collector contacts are located on the backface of the cell.

For the purpose of the present disclosure, the term “concatenation” refers to an unbranched, row-like assembly of two or more elements.

For the purpose of the present disclosure, the term “collinear” refers to a collinear relationship, when viewed along the direction normal to the plane defined by the polymer substrate of the polymer socket.

For the purpose of the present disclosure, the term “linearly arranged contact set” refers to a plurality of the same type of contacts (either collector or emitter) arranged in-line.

In the concatenation of the present invention, a planar, electrically insulating polymer substrate of a polymer socket provides an effective solution by acting like a selective grid that allows electrical contacts in some regions while being electrically insulating in others. The present invention represents an improvement over existing cumbersome solutions for electrically connecting back-contact photovoltaic cells, such as for example dielectric coatings requiring selective application, for example by screen printing, to the backface of a back-contact cell to electrically insulate certain regions of the back-contact cell.

The present invention provides for a concatenation of interconnected polymer sockets each for accepting and electrically connecting a back-contact photovoltaic cell having at least one set of linearly arranged backface emitter contacts and at least one set of linearly arranged backface collector contacts. Each polymer socket comprises (a) a planar, electrically insulating polymer substrate comprising perforations coinciding with the backface emitter contacts, and (b) at least one electrical conductor that is collinear with the perforations of the planar polymer substrate coinciding with the at least one set of linearly arranged backface emitter contacts. The at least one electrical conductor is adhered to the backface of the planar polymer substrate, wherein the at least one electrical conductor of each polymer socket, except the last one in the concatenation, is adhered to the frontface of one adjacent polymer socket so as to be collinear with the at least one set of linearly arranged backface collector contacts of the back-contact photovoltaic cell to be accepted and electrically connected by the adjacent polymer socket. The back-contact photovoltaic cells to be accepted and electrically connected by adjacent polymer sockets are rotated by 180° with respect to each other.

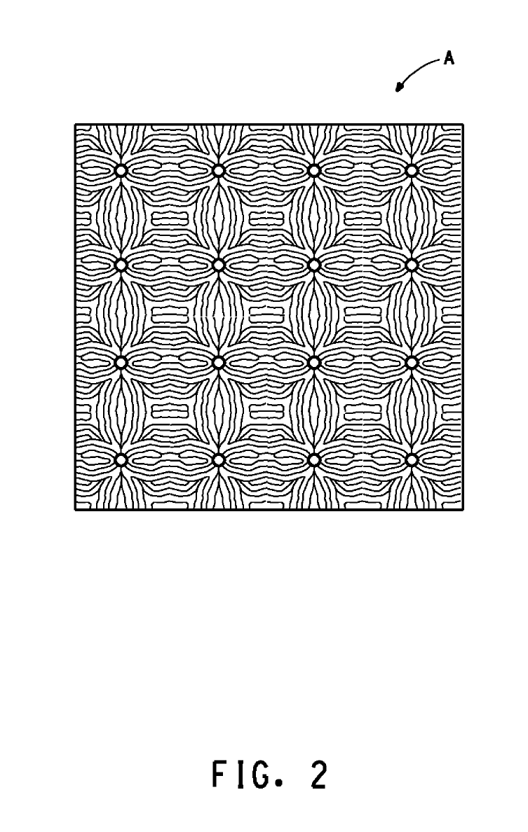

FIG. 2 shows the frontface of a MWT photovoltaic cell A. The lines that can be seen on the surface of the MWT back-contact photovoltaic cell are emitter contact lines comprised of a conductive material such as silver. The lines connect to a pluralitiy of spaced electrical vias that can be seen in FIG. 2 and which connect through the photovoltaic cell to backface emitter contacts on the back of the cell.

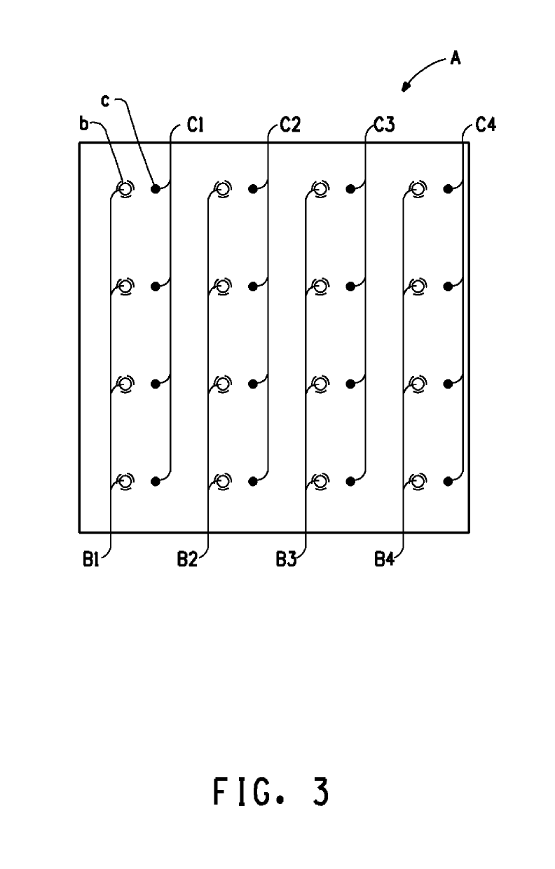

FIG. 3 shows the backface of a MWT photovoltaic cell A having four sets (B1, B2, B3, B4) of linearly arranged backface emitter contacts b and four sets (C1, C2, C3, C4) of linearly arranged backface collector contacts c.

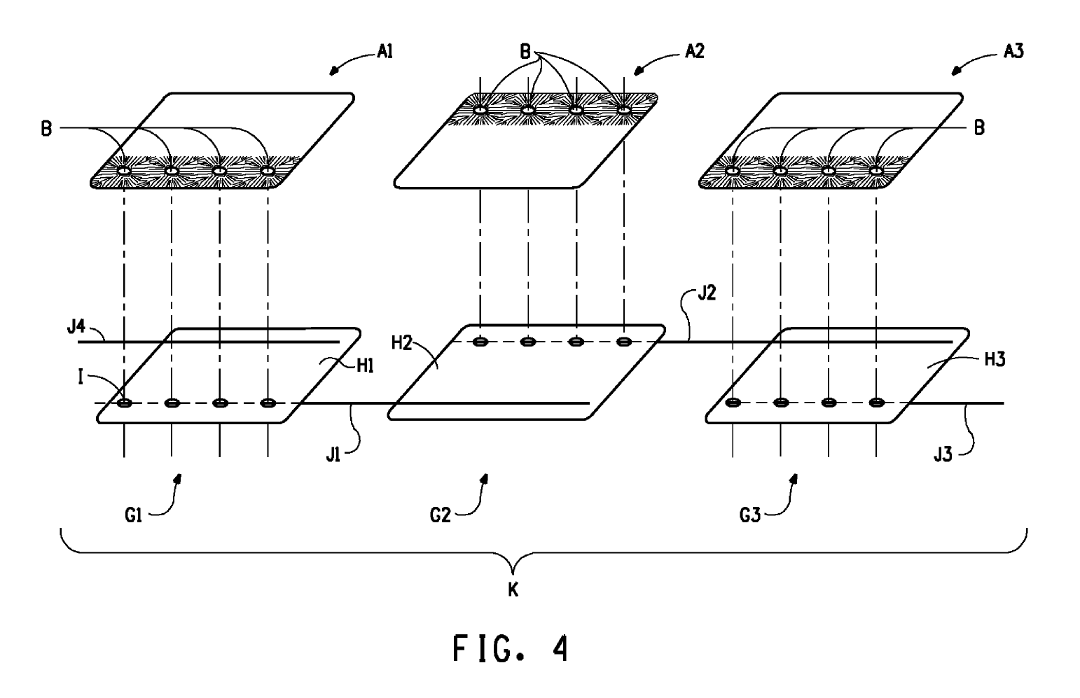

FIG. 4 shows an illustrative embodiment with a plurality of MWT photovoltaic cells (A1, A2, A3) of a back-contact photovoltaic module. A plurality of polymeric sockets (G1, G2, G3) comprising planar, electrically insulating polymer substrates (H1, H2, H3) are provided on the back side of each of the MWT cells. The polymeric sockets (G1, G2, G3) have perforations I coinciding with a set of linearly arranged backface emitter contacts (B) of the MWT photovoltaic cells to be accepted by the corresponding sockets.

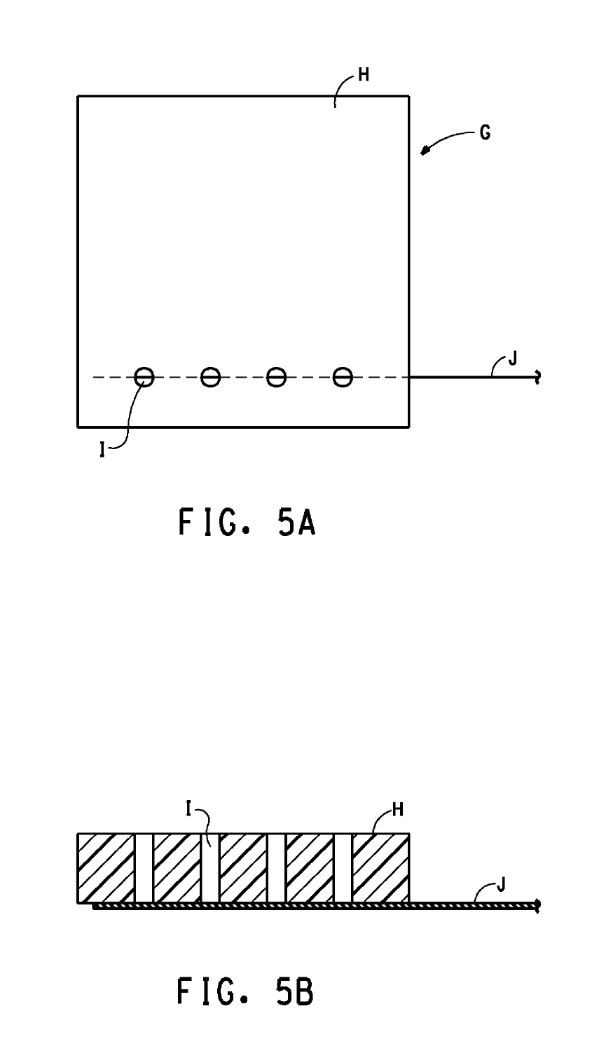

FIG. 5A shows the frontface of a planar, electrically insulating polymer substrate H of a polymeric socket G having perforations I to coincide with a row of linearly arranged backface emitter contacts of a MWT photovoltaic cell to be accepted by the socket. An electrical conductor J is collinear with the perforations I and is adhered to the backface of the polymer substrate. FIG. 5B shows a cross-sectional side view of the electrically insulating polymer substrate H along the electrical conductor J. The substrate has perforations I, and the conductor J is shown adhered to the backface of the polymer substrate H.

As shown in FIG. 4, the polymer substrates and MWT cells are interconnected by the electrical conductors (J1, J2, J3, J4) to form a concatenation K of interconnected polymer sockets. The backface emitter contacts of a first cell A1 are electrically connected to the conductor J1 through the perforations I in the polymer substrate. The backface emitter contacts of a first cell A1 are electrically connected to the backface collector contacts of the adjacent cell A2 via the conductor J1. The conductor is collinear with the perforations I coinciding with the set of linearly arranged backface emitter contacts of the MWT cells and the set of linearly arranged backface collector contacts of the MWT photovoltaic cell to be accepted and electrically connected by the adjacent polymer socket. For illustrative purposes, FIG. 4 shows photovoltaic MWT cells with just one row of emitter contacts and just one row of collector contacts, but it is contemplated that back-contact photovoltaic cells with multiple rows of emitter contacts and collector contacts, like the cell shown in FIG. 3, can be electrically connected with polymeric sockets having a corresponding number of electrical conductors.

The at least one electrical conductor may be of any electrically conductive material such as for example, copper, iron, aluminum, tin, silver, gold, and alloys thereof. Preferably, the at least one electrical conductor comprises a copper or aluminum core surrounded by an electrically conductive soldering composition. Examples of electrically conductive soldering compositions are tin-, tin-lead-, or tin-lead-silver-based soldering compositions.

The at least one electrical conductor may be in the form of for example, a flattened wire or ribbon, round wire, printed circuit board (PCB), and preferably is in the form of a flattened wire.

The at least one electrical conductor is collinear with the at least one set of linearly arranged backface emitter contacts of each back-contact cell to be accepted and electrically connected by each polymer socket, and also with the perforations of the planar polymer substrate coinciding with the at least one set of linearly arranged backface emitter contacts. Thus, the at least one set of linearly arranged backface emitter contacts can be electrically connected to the electrical conductor through the perforations, for example by soldering.

The at least one electrical conductor is located on the backface of the planar polymer substrates, i.e. it is separated, and electrically insulated, from the back-contact photovoltaic cell located on the frontface of the polymer substrate by the polymer substrate itself where the polymer substrate is unperforated.

The concatenation of interconnected polymer sockets is formed by interconnecting the polymer sockets such that the backface of the polymer substrate of each socket, except the last one in said concatenation, is connected to the frontface of the polymer substrate of one adjacent polymer socket by adhering electrical conductor to the backface and frontface of adjacent polymer substrates of the polymer sockets. Stated alternatively, the concatenation is formed by stringing together the polymer sockets by electrical conductors such that the backface of the polymer substrate of each socket, except the last one in the concatenation, is connected to the frontface of the polymer substrate of one adjacent polymer socket by said electrical conductors.

The at least one electrical conductor of each polymer socket of the concatenation of interconnected polymer sockets is adhered to the backface of the planar polymer substrate of said socket such that it is collinear with the perforations coinciding with the at least one set of linearly arranged backface emitter contacts of the back-contact photovoltaic cell to be accepted and electrically connected by the polymer socket. The conductor is adhered as well to the frontface of the planar polymer substrate of one adjacent polymer socket, except the last one in said concatenation, such that it is collinear with the at least one set of linearly arranged backface collector contacts of the back-contact photovoltaic cell to be accepted and electrically connected by the one adjacent polymer socket.

The concatenation of interconnected polymer sockets may comprise any desired number of interconnected polymer sockets. Typical concatenations may comprise of from 2 to 24 polymer sockets, from 2 to 12 polymer sockets or from 2 to 9 polymer sockets.

The at least one electrical conductor may be adhered to the planar polymer substrate of a polymer socket by a suitable adhesive, or is preferably adhered by heating the electrical conductor to a temperature above the melting temperature (Tₘ) of the polymer of the planar polymer substrate and pressing the electrical conductor against the planar polymer substrate until the temperature of the conductor drops below the melting temperature of the polymer of the planar polymer substrate, and releasing the previously applied pressure.

The at least one electrical conductor may be heated to a temperature above the melting temperature (Tₘ) of the polymer of the planar polymer substrate by methods known in the art of photovoltaic applications, such as for example induction heating, sonic vibration heating or thermosonic vibration heating, press heating, heated rolls, heated pins or infrared heating.

The planar, electrically insulating polymer substrate of each polymer socket may further comprises additional perforations coinciding with the backface collector contacts of the back-contact photovoltaic cell to be accepted and connected by the polymer socket. In the case where the planar, electrically insulating polymer substrate of each polymer socket comprises perforations coinciding with the at least one set of linearly arranged backface collector contacts, as well as perforations coinciding with the at least one set of linearly arranged backface emitter contacts of the back-contact photovoltaic cell to be accepted and electrically connected, the perforations coinciding with the set of linearly arranged backface collector contacts of the polymer substrate of one polymer socket are collinear with the perforations coinciding with a set of linearly arranged backface emitter contacts of the polymer substrate of the adjacent polymer socket.

The planar polymer substrate of each polymer socket of the concatenation of interconnected polymer sockets may exhibit the behavior of an elastomeric thermoplastic polymer. Preferably, the planar polymer substrate of the polymer socket comprises or consists of at least one elastomeric thermoplastic polymer.

Because the concatenation according to the present invention is intended for integration into a photovoltaic module, suitable elastomeric thermoplastic polymers may be chosen among polymers having a melting temperature (Tₘ) in excess of the temperature applied in the lamination process step of the photovoltaic module manufacturing processes, in order to prevent damage to the planar polymer substrate of the polymer socket.

The elastomeric thermoplastic polymers may be chosen, for example among styrenic block copolymers, polyolefin blends, elastomeric alloys such as engineering thermoplastic vulcanizates (ETPVs), ionomers, thermoplastic polyurethanes, thermoplastic copolyester and thermoplastic polyamides. Preferably, the planar, electrically insulating polymer substrate comprises a styrenic block copolymer such as styrene-butadiene-styrene block copolymer (SBS), styrene-isoprene-styrene block copolymers (SIS), styrene-ethylene/butylene-styrene block copolymers (SEBS) and styrene-ethylene/propylene-styrene block copolymer (SEPS) or thermoplastic copolyester such as polyester-polyether copolymers.

The present invention further provides for a process for manufacturing a concatenation of interconnected polymer sockets each for accepting and electrically connecting a back-contact photovoltaic cell having at least one set of linearly arranged backface emitter contacts and at least one set of linearly arranged backface collector contacts, the process comprising the steps of (a) providing planar, electrically insulating polymer substrates having perforations coinciding with the backface emitter contacts of the back-contact photovoltaic cells to be accepted and electrically connected by the polymer sockets comprising the polymer substrates, and (b) interconnecting said planar, electrically insulating polymer substrates to form the concatenation of interconnected polymer sockets, such that the backface of each polymer substrate, except the last one in said concatenation, is connected to the frontface of one adjacent polymer substrate by at least one electrical conductor. The conductor is collinear with (i) the perforations of the planar, electrically insulating polymer substrate coinciding with the at least one set of linearly arranged backface emitter contacts of the back-contact photovoltaic cells to be accepted and electrically connected by each of the polymer sockets comprising said substrates, and (ii) the at least one set of linearly arranged backface collector contacts of the back-contact photovoltaic cell to be accepted and connected by the one adjacent polymer socket.

The back-contact photovoltaic cells to be accepted and electrically connected by adjacent polymer sockets are rotated by 180° with respect to each other. The rotation of the photovoltaic cells by 180° in the plane of the photovoltaic cell with respect to each other has the result that the linearly arranged emitter contact sets of a first photovoltaic cell are aligned or collinear with the linearly arranged collector contact sets of the adjacent photovoltaic cell, and the emitter and collector contacts of adjacent cells may be electrically connected by at least one electrical conductor that is straight in the direction of concatenation.

Back-contact cells useful in the present invention may be chosen among MWT cells, BJ cells, IBC cells and EWT cells, and are preferably MWT cells. More preferably, the back-contact cells useful in the present invention may be chosen among back-contact cells having the backface emitter contacts and the backface collector contacts coated with an electrically conductive soldering composition. Examples of electrically conductive soldering compositions are tin-, tin-lead-, or tin-lead-silver-based soldering compositions. Preferably, the back-contact cells useful in the present invention may be chosen among “symmetrical” back-contact cells, i.e. back-contact cells having the same number of linearly arranged backface emitter contact sets and of linearly arranged backface collector contact sets. More preferably, in the “symmetrical” back-contact cells, the sets of linearly arranged backface emitter contacts and the sets of linearly arranged backface collector contacts alternate.

The planar, electrically insulating polymer substrate of each polymer socket may be obtained, for example, by injection molding the polymer (e.g. elastomeric thermoplastic polymer) into the desired shape, by cutting out the desired shape from a sheet of polymer (e.g. elastomeric thermoplastic polymer), or by laminating different layers of polymer (e.g. elastomeric thermoplastic polymer) together.

The planar, electrically insulating polymer substrate of each polymer socket may further have perforations coinciding with the backface collector contacts of the back-contact photovoltaic cells to be accepted and electrically connected by the interconnected polymer sockets of the concatenation.

The interconnection of the polymer sockets to form the concatenation according to the present invention may be carried out manually or using automatic equipment. A suitable automatic equipment to interconnect the polymer sockets may be a so-called “tabber-stringer” that has been modified to process the planar, electrically insulating polymer substrates of the polymer sockets. Conventionally, tabber-stringers are used to string together photovoltaic cells, or so-called “H cells”. The tabbing unit generally serves to place and orient the photovoltaic cells, before the stringing unit strings the photovoltaic cells together with electrical conductor by first adhering the electrical conductor to the backface contacts of a first H cell and then adhering the electrical conductor to the frontface contacts of the next H cell in line. Substituting the photovoltaic cells in the tabbing unit of the tabber-stringer with planar, electrically insulating polymer substrates will result in the tabber-stringer interconnecting the polymer substrates such that the backface of a first polymer substrate is connected to the frontface of the next adjacent polymer substrate through at least one electrical conductor by adhering said electrical conductor to the backface of a first polymer substrate as well as to the frontface of the next adjacent polymer substrate.

The tabber-stringer may adhere the electrical conductor to the planar, electrically insulating polymer substrate by heating the conductor to a temperature above the melting temperature of the polymer of the planar polymer substrate and by pressing the electrical conductor against the backface of the planar polymer substrate until the temperature of the conductor drops below the melting temperature of the polymer of the planar polymer substrate, and then releasing the previously applied pressure. The heating of the electrical conductor may be achieved by methods known in the art of photovoltaic applications, such as for example induction heating, sonic vibration heating or thermosonic vibration heating, press heating, heated rolls, heated pins, or infra-red heating.

A person skilled in the art of automatic equipment for tab-stringing together photovoltaic cells will be able to modify a conventional tabber-stringer such that it strings together, or interconnects, the planar polymer substrates instead of photovoltaic cells by replacing the photovoltaic cells in the tabber-stringer with the planar, electrically insulating polymer substrates.

In an embodiment, the process according to the present invention further comprises the steps of (c) accepting back-contact photovoltaic cells on the planar, electrically insulating polymer substrates, and (d) electrically connecting the linearly arranged backface emitter contacts and the linearly arranged backface collector contacts of back-contact photovoltaic cells of adjacent polymer sockets by at least one electrical conductor, preferably by soldering to form a concatenation of interconnected polymer sockets each having accepted and electrically connected a back-contact photovoltaic cell.

A robot may be used to place the back-contact photovoltaic cells on the planar, electrically insulating polymer substrates such that they may be accepted and subsequently electrically connected to the electrical conductors by way of soldering said conductors to the sets of linearly arranged backface emitter contacts and the sets of linearly arranged backface collector contacts of the back-contact photovoltaic cells through the perforations.

In the case where soldering is achieved by heated rolls, the rolls are preferably dented such that the dents push the at least one electrical conductors through the perforations in the planar, electrically insulating polymer substrate such that they can contact the backface emitter contacts of the back-contact cell.

1. A concatenation of interconnected polymer sockets each for accepting and electrically connecting a back-contact photovoltaic cell having at least one set of linearly arranged backface emitter contacts and at least one set of linearly arranged backface collector contacts, each polymer socket comprising
a. a planar, electrically insulating polymer substrate comprising perforations coinciding with the at least one set of linearly arranged backface emitter contacts of a back-contact photovoltaic cell to be accepted and electrically connected by the polymer socket, said substrate having a frontface and backface on opposite sides of the substrate, the frontface being on the side of the substrate on which the back-contact photovoltaic cell is to be accepted and electrically connected by the polymer socket, and
b. at least one electrical conductor being collinear with the perforations of the planar polymer substrate coinciding with the at least one set of linearly arranged backface emitter contacts of a back-contact photovoltaic cell to be accepted and electrically connected by the polymer socket, and being adhered to the backface of the planar polymer substrate,
wherein the at least one electrical conductor of each polymer socket, except the last one in said concatenation, is adhered to the frontface of one adjacent polymer socket so as to be collinear with the at least one set of linearly arranged backface collector contacts of the back-contact photovoltaic cell to be accepted and electrically connected by said adjacent polymer socket.

2. The concatenation according to claim 1, wherein the planar, electrically insulating polymer substrate of each polymer socket comprises additional perforations coinciding with the backface collector contacts of the back-contact photovoltaic cell to be accepted and electrically connected by the polymer socket.

3. The concatenation according to claim 1, wherein the planar polymer substrate comprises or consists of at least one elastomeric thermoplastic polymer.

4. The concatenation according to claim 3, wherein the at least one elastomeric thermoplastic polymer is selected from styrenic block copolymers and polyester polyether copolymers.

5. The concatenation of claim 1, wherein each polymer socket has accepted and electrically connected a back-contact photovoltaic cell and wherein the back-contact photovoltaic cells accepted and electrically connected by adjacent polymer sockets are rotated by 180° with respect to each other.

6. A process for manufacturing a concatenation of interconnected polymer sockets each for accepting and electrically connecting a back-contact photovoltaic cell having at least one set of linearly arranged backface emitter contacts and at least one set of linearly arranged backface collector contacts, the process comprising the steps of
a. providing planar, electrically insulating polymer substrates having perforations coinciding with the at least one set of linearly arranged backface emitter contacts of the back-contact photovoltaic cells to be accepted and electrically connected by the polymer sockets comprising said polymer substrates, said substrates each having a frontface and backface on opposite sides of the substrate, the frontface being on the side of the substrate on which the back-contact photovoltaic cell is to be accepted and electrically connected by the polymer socket, and
b. interconnecting said planar, electrically insulating polymer substrates through one or more electrical conductors to form the concatenation of interconnected polymer sockets, such that the backface of each polymer substrate, except the last one in said concatenation, is connected to the frontface of one adjacent polymer substrate by at least one electrical conductor, wherein said conductor is collinear with
i. the perforations of the planar, electrically insulating polymer substrate coinciding with the at least one set of linearly arranged backface emitter contacts of the back-contact photovoltaic cells to be accepted and electrically connected by each of the polymer sockets comprising said substrates, and
the at least one set of linearly arranged backface collector contacts of the back-contact photovoltaic cell to be accepted and connected by the one adjacent polymer socket.

7. The process according to claim 6, wherein the planar, electrically insulating polymer substrates further have perforations coinciding with said at least one set of backface collector contacts of the back-contact photovoltaic cells to be accepted and electrically connected by the polymer sockets.

8. The process according to claim 6 further including the steps of
c. accepting back-contact photovoltaic cells on the planar, electrically insulating polymer substrates wherein the back-contact photovoltaic cells accepted and electrically connected by adjacent polymer sockets are rotated by 180° with respect to each other, and
d. electrically connecting the linearly arranged backface emitter contacts and the linearly arranged backface collector contacts of back-contact photovoltaic cells of adjacent polymer sockets by said at least one electrical conductor.

9. The process according to claim 6, wherein the interconnecting of said planar, electrically insulating polymer substrates through one or more electrical conductors is conducted on tabber-stringer automatic equipment.
